(19) United States
(12) Patent Application Publication
(10) Pub. No.: US 2025/0241169 A1
(43) Pub. Date: Jul. 24, 2025

(54) DISPLAY PANEL AND DISPLAY APPARATUS

(71) Applicant: Hubei Yangtze Industrial Innovation Center Of Advanced Display Co., Ltd., Wuhan (CN)

(72) Inventor: Peng SHEN, Wuhan (CN)

(21) Appl. No.: 19/172,625

(22) Filed: Apr. 7, 2025

(30) Foreign Application Priority Data
Dec. 10, 2024 (CN) 202411817253.8

(51) Int. Cl. H10K 59/40; H10K 59/80

(52) U.S. Cl. CPC H10K 59/40; H10K 59/875

(57) ABSTRACT

A display panel and a display apparatus. The display panel includes a substrate, a touch trace and a first insulating layer, and the touch trace are arranged between the substrate and the first insulating layer. The first insulating layer includes a body portion and an auxiliary portion that are connected to each other. The body portion surrounds to form first openings spaced from one another, and the auxiliary portion is arranged in the first opening. In a thickness direction of the substrate, the body portion covers the touch trace, and the auxiliary portion does not overlap the touch trace. Therefore, the display panel and the display apparatus provided by the present disclosure can reduce the risk of failure of the touch trace.

### CROSS-REFERENCE TO RELATED DISCLOSURE

The present disclosure claims priority to Chinese Patent Application No. 202411817253.8, filed on Dec. 10, 2024, the content of which is incorporated herein by reference in its entirety.

### TECHNICAL FIELD

The present disclosure relates to the field of display technologies, and in particular, to a display panel and a display apparatus.

### BACKGROUND

An organic light emitting diode (OLED) display panel has many advantages such as all-solid-state, active light emission, fast response speed, high contrast, no viewing angle limitation, and flexible display. As a novel display technology developed in the middle of the twentieth century, the OLED display panel has been widely applied in daily production and living activities. In the related art, the display panel includes a substrate and touch traces arranged at a side of the substrate. However, such touch traces are prone to touch failure issues.

### SUMMARY

An aspect of the present disclosure provides a display panel. The display panel includes: a substrate, a touch trace, and a first insulating layer. The touch trace is arranged between the substrate and the first insulating layer. The first insulating layer includes a body portion and an auxiliary portion that are connected to each other. The body portion surrounds to form first openings spaced from one another, and the auxiliary portion is arranged in the first opening. In a thickness direction of the substrate, the body portion covers the touch trace, and the auxiliary portion does not overlap the touch trace.

Another aspect of the present disclosure provides a display apparatus. The display apparatus includes a display panel. The display panel includes: a substrate, a touch trace, and a first insulating layer. The touch trace is arranged between the substrate and the first insulating layer. The first insulating layer includes a body portion and an auxiliary portion that are connected to each other. The body portion surrounds to form first openings spaced from one another, and the auxiliary portion is arranged in the first opening. In a thickness direction of the substrate, the body portion covers the touch trace, and the auxiliary portion does not overlap the touch trace.

### BRIEF DESCRIPTION OF DRAWINGS

FIG. 1 is a top view of a display panel according to an embodiment of the present disclosure.

FIG. 2 is a partial schematic view of FIG. 1. according to an embodiment of the present disclosure

FIG. 3 is a sectional view taken along line A-A of FIG. 1 according to an embodiment of the present disclosure.

FIG. 4 is a sectional view taken along line B-B of FIG. 1 according to an embodiment of the present disclosure.

FIG. 5 is another top view of a display panel according to an embodiment of the present disclosure.

FIG. 6 is a partial schematic view of FIG. 5 according to an embodiment of the present disclosure.

FIG. 7 is a sectional view of a substrate, a second insulating layer and a touch trace according to an embodiment of the present disclosure.

FIG. 8 is a sectional view taken along line C-C of FIG. 5 according to an embodiment of the present disclosure.

FIG. 9 is another sectional view of a substrate, a second insulating layer and a touch trace according to an embodiment of the present disclosure.

FIG. 10 is a sectional view of a display panel according to an embodiment of the present disclosure.

FIG. 11 is another sectional view of a display panel according to an embodiment of the present disclosure.

FIG. 12 is another sectional view of a display panel according to an embodiment of the present disclosure.

FIG. 13 is a partially enlarged view of a light extraction member according to an embodiment of the present disclosure.

100. display panel; 101. substrate; 102. touch trace; 110. first insulating layer; 111. first opening; 1111. first sidewall; 112. body portion; 1121. first surface; 113. auxiliary portion; 1132. second surface; 1132a. first end; 1132b. second end; 114. notch; 120. second insulating layer; 131. first embedding portion; 1311. first embedding sub-portion; 1313. third embedding sub-portion; 132. second embedding portion; 1322. second embedding sub-portion; 1324. fourth embedding sub-portion; 140. light extraction member; 143. third surface; 144. fourth surface.

### DESCRIPTION OF EMBODIMENTS

To facilitate understanding of the present disclosure, the present disclosure will be described more fully below with reference to the drawings. Preferred embodiments of the present disclosure are shown in the drawings. However, the present disclosure can be implemented in many different manners and is not limited to the embodiments described herein. Rather, these embodiments are provided to provide a more thorough and comprehensive understanding of the present disclosure.

Unless otherwise defined, all technical and scientific terms used herein have the same meaning as commonly understood by those skilled in the art pertaining to the present disclosure. The terms used herein in the specification of the present disclosure are for the purpose of describing specific embodiments only, and are not intended to limit the present disclosure. As used herein, the term “and/or” includes any and all combinations of one or more associated listed items.

In describing positional relationships, unless otherwise specified, when an element such as a layer, a film or a substrate is referred to as being “on” another element, it can be directly on the other element or intervening elements may also be present. Further, when a layer is referred to as being “under” another layer, it may be directly under, or one or more intervening elements may also be present. It is also understood that when a layer is referred to as being “between” two layers, it may be the only layer between the two layers, or one or more intervening elements may also be present.

In the case where “including”, “having”, and “including” as described herein are used, another component may also be added unless a well-defined term is used, such as “only”, “consisting of”. Unless mentioned to the contrary, terms in singular form may include plural forms, and cannot be understood as one.

It should be understood that, although the terms “first”, “second”, etc. may be used herein to describe various elements, these elements should not be limited by these terms. These terms are only used to distinguish one element from another. For example, a first element may be referred to as a second element, and similarly, a second element may be referred to as a first element, without departing from a scope of the present disclosure.

It should also be understood that when interpreting an element, although not explicitly described, the element is interpreted to include an error range that should be within an acceptable deviation range from a particular value as determined by those skilled in the art. For example, “about”, “approximately”, or “substantially” may mean within one or more standard deviations, which is not limited herein.

In addition, in the specification of the present disclosure, the phrase “planar distribution schematic” refers to a drawing when a target portion is viewed from above, and the phrase “sectional schematic” refers to a drawing when a section taken by vertically cutting the target portion is viewed from the side.

In addition, the drawings are not drawn to a scale of 1:1, and relative sizes of the elements in the drawings are drawn only as examples and are not necessarily drawn to a true scale.

Those skilled in the art can make various modifications and variations in the present disclosure without departing from the scope of the present disclosure. Accordingly, the present disclosure is intended to cover the modifications and variations of the present disclosure that fall within the scope of corresponding claims (claimed technical solutions) and their equivalents. It should be noted that, the implementations provided in the embodiments of the present disclosure can be combined with each other if no conflict occurs.

As described in the background section, in the related art, the display panel includes a substrate and a touch trace arranged at a side of the substrate. An optical transparent adhesive with a high refractive index is provided at a side of the touch trace facing away from the substrate, and the optical transparent adhesive covers a surface of a side of the touch trace facing away from the substrate and a sidewall of the touch trace. However, a width of the optical transparent adhesive is the same along a direction perpendicular to an extending direction of the touch trace, and the width is about 5 μm, so that the width of the optical transparent adhesive is smaller. A contact area between the optical transparent adhesive and an underlying film layer is small, resulting in poor connection stability between the optical transparent adhesive and the substrate, and causing easy peeling of the optical transparent adhesive and the lower film layer. As a result, the optical transparent adhesive and the substrate are easy to peel off, preventing effective coverage of the touch trace by the optical transparent adhesive, and causing easy peeling of the touch trace and the substrate, thereby adversely affecting the touch performance of the touch trace, and ultimately leading to the failure of the touch trace.

Based on the above technical problems, the research found that the first insulating layer is arranged at a side of the touch trace facing away from the substrate. The first insulating layer includes a body portion and an auxiliary portion that are connected to each other. The body portion surrounds to form first openings spaced from one another, and the auxiliary portion is arranged at a side of the body portion facing one of the first openings. In a thickness direction of the substrate, the body portion covers the touch trace, and the auxiliary portion does not overlap the touch trace. In this way, compared to configurations with only the body portion, the display panel provided by the embodiments of the present disclosure achieves an increased total area of the body portion and the auxiliary portion by providing the auxiliary portion, enhancing the connection stability between the first insulating layer and the substrate. The enhanced connection stability makes peeling off the first insulating layer and the substrate more difficult to peel off compared to prior art, so that the first insulating layer can maintain a better coverage over the touch trace, thereby preventing easy peeling off of the touch trace from the substrate, ensuring the touch performance of the touch trace, and reducing the risk of failure of the touch trace.

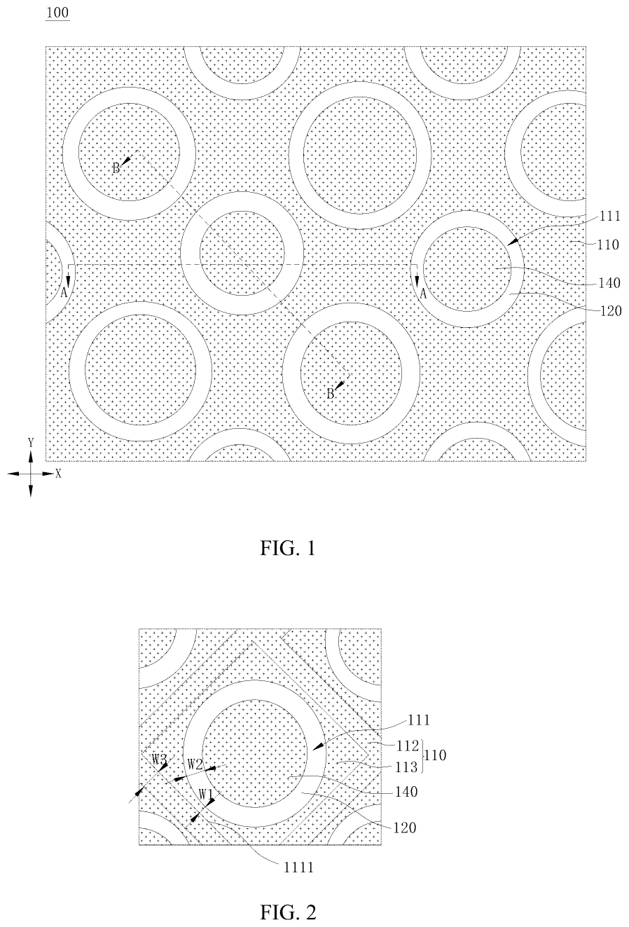

The above content shows a core idea of the present disclosure, and the following clearly and completely describes the technical solutions in the embodiments of the present disclosure with reference to the drawings in the embodiments of the present disclosure. A display apparatus provided by an embodiment of the present disclosure will be described with reference to FIG. 1 to FIG. 13.

An embodiment of the present disclosure provides a display apparatus, which may include the display panel 100 in any one of the following embodiments. Therefore, the display apparatus also has the beneficial effects of the display panel 100 in the following embodiments, and the same details can be understood with reference to the following explanation of the display panel 100, which will not be repeated herein.

In some embodiments of the present disclosure, the display apparatus may be a phone or any electronic product having a display function, including but not limited to the following categories: a television, a laptop, a desktop display, a tablet computer, a digital camera, a smart bracelet, smart glasses, an in-vehicle display, an environmental control device, a medical display screen, a touch interaction terminal, and the like, which will not be limited in embodiments of the present disclosure.

In some embodiments of the present disclosure, the display panel 100 may include an organic light emitting diode (OLED) display panel, a quantum dot light emitting diode (QLED) display panel, a mini light emitting diode display (Mini LED) or a micro light emitting diode display (Micro LED). In an embodiment of the present disclosure, the display panel 100 is an OLED display panel for example.

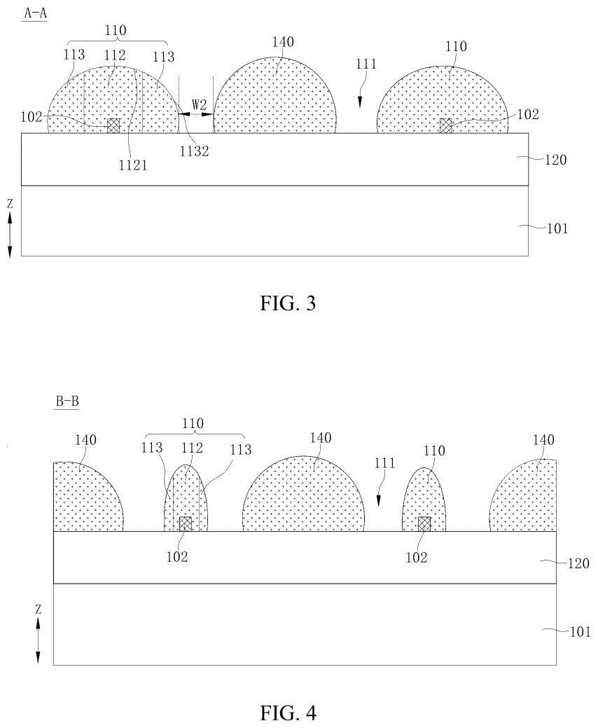

Referring to FIG. 1 and FIG. 3, the display panel 100 may have a first direction X, a second direction Y and a third direction Z that are different from each other. The first direction X and the second direction Y may be any two different directions parallel to the display panel 100, and the third direction Z may be any direction intersecting with a plane parallel to the display panel 100. For example, the first direction X, the second direction Y, and the third direction Z may be perpendicular to each other. In some embodiment of the present disclosure, the first direction X may be a length direction of the display panel 100, the second direction Y may be a width direction of the display panel 100, and the third direction Z may be a thickness direction of the display panel 100. The length, width, and thickness in the embodiments of the present disclosure are merely for ease of description, and do not mean any limitation on a size. For example, the width may be greater than, equal to, or less than the length.

An embodiment of the present disclosure provides a display panel 100, referring to FIG. 3 and FIG. 4. The display panel 100 may include a substrate 101 and a touch trace 102 arranged at a side of the substrate 101, and the substrate 101 may provide support for other structural layers that are subsequently arranged The touch trace 102 may be configured to implement a touch function.

Referring to FIG. 2 and FIG. 3, the display panel 100 may include a first insulating layer 110 arranged at a side of the touch trace 102 facing away from the substrate 101. The first insulating layer 110 may include a body portion 112 and an auxiliary portion 113 that are connected to each other. The body portion 112 surrounds to form first openings 111 spaced from one another, and the auxiliary portion 113 is arranged at a side of the body portion 112 facing the first opening 111, that is, the auxiliary portion 113 is located in the first opening 111. In the thickness direction (i.e., the third direction Z) of the substrate 101, the body portion 112 covers the touch trace 102 (at the corresponding position), and the auxiliary portion 113 does not overlap the touch trace 102 (at the corresponding position). In this way, by configuring the body portion 112 to cover a side surface of the touch trace 102 facing away from the substrate 101 and a sidewall of the touch trace 102, the touch trace 102 is prevented from being exposed. By configuring the auxiliary portion 113, a total area of the body portion 112 and the auxiliary portion 113 is larger, enhancing the connection stability between the first insulating layer 110 and the substrate 101. The first insulating layer 110 is not easy to peel off from the substrate 101, so that the first insulating layer 110 can maintain a better coverage over the touch trace 102, thereby preventing easy peeling off of the touch trace 102 from the substrate 101, ensuring the touch performance of the touch trace 102 and reducing the risk of failure of the touch trace 102. For example, the auxiliary portion 113 may be arranged corresponding to the first opening 111, and the auxiliary portion 113 may be located in the corresponding first opening 111.

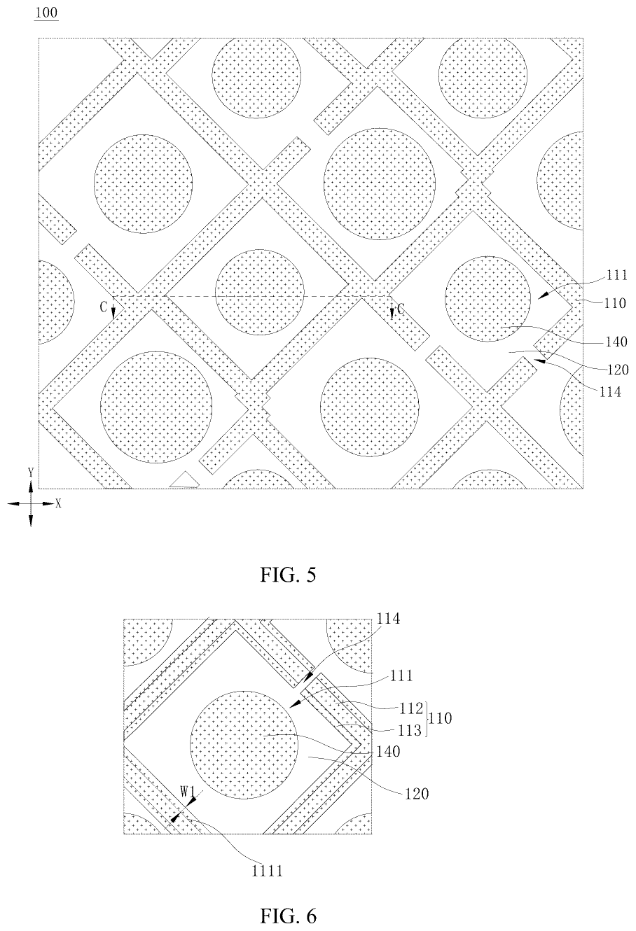

The body portion 112 surrounds to form the first openings 111 that are spaced from one another. Along a circumferential direction of the first opening 111, the first openings 111 may be closed openings, or the first openings 111 may be unclosed openings. Referring to FIG. 2, in a same first opening 111, when the first opening 111 is a closed opening along the circumferential direction of the first opening 111, it is equivalent that the body portion 112 encloses first openings 111 that are spaced from one another. In an embodiment of the present disclosure, referring to FIG. 5 and FIG. 6, in the same first opening 111, when the first opening 111 is an unclosed opening along the circumferential direction of the first opening 111, a notch 114 may be further formed at the first insulating layer 110, and the notch 114 may be in communication with two adjacent first openings 111. At least part of two adjacent first openings 111 may be provided with a notch 114. It should be noted that at the notch 114, there may be a touch trace not covered by the first insulating layer.

In some embodiment of the present disclosure, the material of the first insulating layer 110 may include an optical transparent adhesive.

In some embodiments, referring to FIG. 3, the display panel 100 further includes a second insulating layer 120 that is arranged between the touch trace 102 and the substrate 101

In some embodiments, the second insulating layer 120 may include a first sub-insulating layer that may be an inorganic encapsulation layer. A light-emitting device layer is provided between the substrate 101 and the first sub-insulating layer, and the first sub-insulating layer may prevent water and oxygen from invading the light-emitting device layer, thereby forming encapsulation protection for the light-emitting device layer.

In some embodiments, the second insulating layer 120 may include a second sub-insulating layer that is arranged at a side of the first sub-insulating layer facing away from the substrate 101. The second sub-insulating layer may be a buffer layer that may be formed of an inorganic material or an organic material. The buffer layer may be configured to prevent subsequent etching from damaging the first sub-insulating layer, thereby improving the packaging effect of the display panel 100.

In some embodiments, the second insulating layer 120 may include a third sub-insulating layer that is arranged at a side of the second sub-insulating layer facing away from the substrate 101. A material of the third sub-insulating layer may include an inorganic material. The display panel 100 may further include an auxiliary touch trace, and the touch trace 102 may be arranged at a side of the auxiliary touch trace facing away from the substrate 101. The third sub-insulating layer is arranged between the touch trace 102 and the auxiliary touch trace.

In some other embodiments, the display panel 100 may include only the touch trace 102 without providing the auxiliary touch trace. An embodiment of the present disclosure is described by using an example in which both the touch trace 102 and the auxiliary touch trace are arranged. One of the auxiliary touch trace and the touch trace 102 may be a bridging layer, and another one of the auxiliary touch trace and the touch trace 102 may be a touch function layer. An embodiment of the present disclosure is described by using an example in which the auxiliary touch trace is a bridging layer and the touch trace 102 is a touch function layer.

In some embodiment of the present disclosure, a material of at least one of the first sub-insulating layer, the second sub-insulating layer, and the third sub-insulating layer includes at least one of silicon nitride, silicon oxide, and silicon oxynitride.

A first embedding portion 131 and a second embedding portion 132 provided in the embodiments of the present disclosure will be described below.

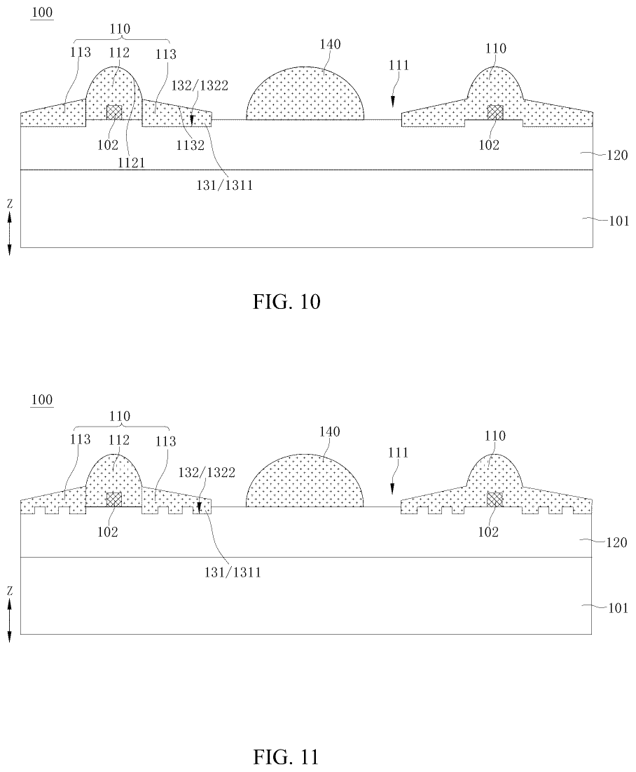

In some embodiments, referring to FIG. 10 to FIG. 12, a first embedding portion 131 is provided at a side of the first insulating layer 110 facing the substrate 101, and a second embedding portion 132 is provided at a side of the second insulating layer 120 facing away from the substrate 101. In other words, the first embedding portion 131 is provided at a side of the first insulating layer 110 facing the second insulating layer 120, and the second embedding portion 132 is provided at a side of the second insulating layer 120 facing the first insulating layer 110. The first embedding portion 131 and the second embedding portion 132 are embedded with each other. In this way, by providing the first embedding portion 131 and the second embedding portion 132 that cooperate with each other, the contact area between the first insulating layer 110 and the second insulating layer 120 can be increased, which enhances the connection stability between the first insulating layer 110 and the second insulating layer 120, so as to enhance the connection stability between the first insulating layer 110 and the substrate 101. As a result, the first insulating layer 110 and the substrate 101 are not easy to peeled off, so that the first insulating layer 110 can maintain a better coverage over the touch trace 102, thereby preventing easy peeling off of the touch trace 102 from the substrate 101, ensuring the touch performance of the touch trace 102 and reducing the risk of failure of the touch trace 102.

In some embodiments, referring to FIG. 10 and FIG. 11, the first embedding portion 131 includes a first embedding sub-portion 1311 arranged on the auxiliary portion 113, and the first embedding sub-portion 1311 is arranged at a side of the auxiliary portion 113 facing the second insulating layer 120. The second embedding portion 132 includes a second embedding sub-portion 1322 arranged on the second insulating layer 120 corresponding to the auxiliary portion 113. The first embedding sub-portion 1311 and the second embedding sub-portion 1322 are embedded with each other. In this way, by providing the first embedding sub-portion 1311 and the second embedding sub-portion 1322, the contact area between the first insulating layer 110 and the second insulating layer 120 can be increased, which enhances the connection stability between the first insulating layer 110 and the second insulating layer 120, so as to enhance the connection stability between the first insulating layer 110 and the substrate 101. As a result, the first insulating layer 110 and the substrate 101 are not easy to peeled off, so that the first insulating layer 110 can maintain a better coverage over the touch trace 102, preventing easy peeling off of the touch trace 102 from the substrate 101, thereby ensuring the touch performance of the touch trace 102 and reducing the risk of failure of the touch trace 102.

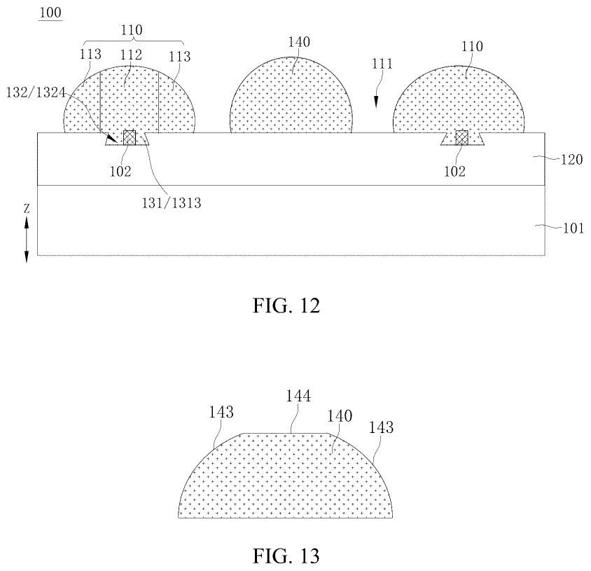

In some embodiments, referring to FIG. 12, the first embedding portion 131 includes a third embedding sub-portion 1313 arranged on the body portion 112, and the third embedding sub-portion 1313 is arranged at a side of the body portion 112 facing the second insulating layer 120. The second embedding portion 132 includes a fourth embedding sub-portion 1324 arranged on the second insulating layer 120 corresponding to the body portion 112. The third embedding sub-portion 1313 and the fourth embedding sub-portion 1324 are embedded with each other. In this way, by providing the third embedding sub-portion 1313 and the fourth embedding sub-portion 1324 that cooperate with each other, the contact area between the first insulating layer 110 and the second insulating layer 120 can be increased, so that the touch trace 102 and the substrate 101 are not easy to peeled off, thereby ensuring the touch performance of the touch trace 102 and reducing the risk of failure of the touch trace 102. The principle thereof has been described and will not be repeated.

The first embedding portion 131 may include at least one of the first embedding sub-portion 1311 and the third embedding sub-portion 1313, and the second embedding portion 132 may include at least one of the second embedding sub-portion 1322 and the fourth embedding sub-portion 1324. In an embodiment in which the first embedding portion 131 includes both the first embedding sub-portion 1311 and the third embedding sub-portion 1313, and the second embedding portion 132 includes both the second embedding sub-portion 1322 and the fourth embedding sub-portion 1324, the contact area between the first insulating layer 110 and the second insulating layer 120 can be increased, thereby ensuring the touch performance of the touch trace 102 and reducing the risk of failure of the touch trace 102.

In an embodiment in which the first embedding sub-portions 1311 are provided on the auxiliary portion 113, the number of the first embedding sub-portions 1311 on the same auxiliary portion 113 may be at least one. Referring to FIG. 11, when there are multiple first embedding sub-portions 1311 on the same auxiliary portion 113, the first embedding sub-portions 1311 may be spaced from one another. Correspondingly, multiple second embedding sub-portions 1322 are provided on a portion of the second insulating layer 120 corresponding to the auxiliary portion 113. The first embedding sub-portion 1311 is correspondingly arranged with the second embedding sub-portion 1322, and the first embedding sub-portion 1311 and the corresponding second embedding sub-portion 1322 are embedded with each other. In this way, by providing multiple first embedding sub-portions 1311 and multiple second embedding sub-portions 1322 that cooperate with each other, the contact area between the first insulating layer 110 and the second insulating layer 120 can be increased, so that the touch trace 102 and the substrate 101 are not easy to peeled off, thereby ensuring the touch performance of the touch trace 102 and reducing the risk of failure of the touch trace 102. The principle thereof has been described and will not be repeated.

In an embodiment in which the auxiliary portion 113 is provided with multiple first embedding sub-portions 1311, the first embedding sub-portions 1311 may be spaced from one another in a direction from the body portion 112 to the auxiliary portion 113.

Referring to FIG. 12, in an embodiment in which the body portion 112 is provided with the third embedding sub-portions 1313, the number of the third embedding sub-portions 1313 may be at least one. When there are multiple third embedding sub-portions 1313, multiple fourth embedding sub-portions 1324 are provided on a portion of the second insulating layer 120 corresponding to the body portion 112 correspondingly, and the third embedding sub-portion 1313 is correspondingly arranged with the fourth embedding sub-portion 1324. The third embedding sub-portion 1313 and the corresponding fourth embedding sub-portion 1324 are embedded with each other.

In some embodiments, one of the first embedding portion 131 and the second embedding portion 132 is a groove, the other of the first embedding portion 131 and the second embedding portion 132 is a protrusion, and the groove and the protrusion are embedded with each other. In an embodiment provided with the first embedding sub-portion 1311 and the second embedding sub-portion 1322, the first embedding sub-portion 1311 may be a groove, and the second embedding sub-portion 1322 may be a protrusion. In an embodiment of the present disclosure, the first embedding sub-portion 1311 may be a protrusion, and the second embedding sub-portion 1322 may be a groove. In an embodiment provided with the third embedding sub-portion 1313 and the fourth embedding sub-portion 1324, the third embedding sub-portion 1313 may be a groove, and the fourth embedding sub-portion 1324 may be a protrusion. In an embodiment of the present disclosure, the third embedding sub-portion 1313 may be a protrusion, and the fourth embedding sub-portion 1324 may be a groove.

Referring to FIG. 9 and FIG. 10, taking the second embedding portion 132 as a groove as an example, the groove is formed at the second insulating layer 120, and then the first insulating layer 110 is formed. Part of the first insulating layer 110 extends into the groove and forms a protrusion, and the groove and the protrusion are embedded with each other, so that the contact area between the first insulating layer 110 and the second insulating layer 120 can be increased, an adhesive force of a film layer between the first insulating layer 110 and the second insulating layer 120 becomes stronger, and the first insulating layer 110 and the second insulating layer 120 are not easy to peel off, so as to ensure that the first insulating layer 110 can always cover the touch trace 102 and the touch trace 102 is not easy to peel off, thereby ensuring the touch performance of the touch trace 102 and reducing the risk of failure of the touch trace 102. The principle thereof has been described and will not be repeated.

In some embodiment of the present disclosure, referring to FIG. 12, a size of the notch of the groove is smaller than a size of the bottom wall of the groove. Correspondingly, on the protrusion embedded with the groove, a size of an end of the protrusion adjacent to the notch of the groove is smaller than a size of an end of the protrusion adjacent to the bottom wall of the groove. As a result, the size of the notch of the groove is smaller, and the protrusion can be limited in the thickness direction of the substrate 101, so that the groove can be prevented the protrusion from being separated, enhancing the connection stability of the first insulating layer 110 and the second insulating layer 120, and preventing easy peeling off of the touch trace 102 from the substrate 101, thereby ensuring the touch performance of the touch trace 102 and reducing the risk of failure of the touch trace 102. The principle thereof has been described and will not be repeated.

In some embodiment of the present disclosure, an opening size of the groove gradually decreases from a bottom wall of the groove to the notch of the groove. That is, along a section perpendicular to the thickness direction of the substrate 101, a sectional area of the groove gradually decreases from the bottom wall of the groove to the notch of the groove. The sidewall of the groove may be an inclined wall or an arc-shaped wall, so that the opening size of the groove slowly changes from the bottom wall of the groove to the notch of the groove, thereby reducing the manufacturing difficulty of the groove.

In some embodiment of the present disclosure, a depth of the groove ranges from 0.3 μm to 0.5 μm, that is, a size of the groove along the thickness direction of the substrate 101 ranges from 0.3 μm to 0.5 μm, thereby preventing the depth of the groove from being too small, and increasing a contact area between the first insulating layer 110 and the second insulating layer 120. In addition, the depth of the groove can also be prevented from being too large to affect the packaging effect of the second insulating layer 120 on the light-emitting device layer. For example, the depth of the groove may be 0.3 μm, 0.35 μm, 0.4 μm, 0.45 μm, 0.5 μm or any value ranging from 0.3 μm to 0.5 μm.

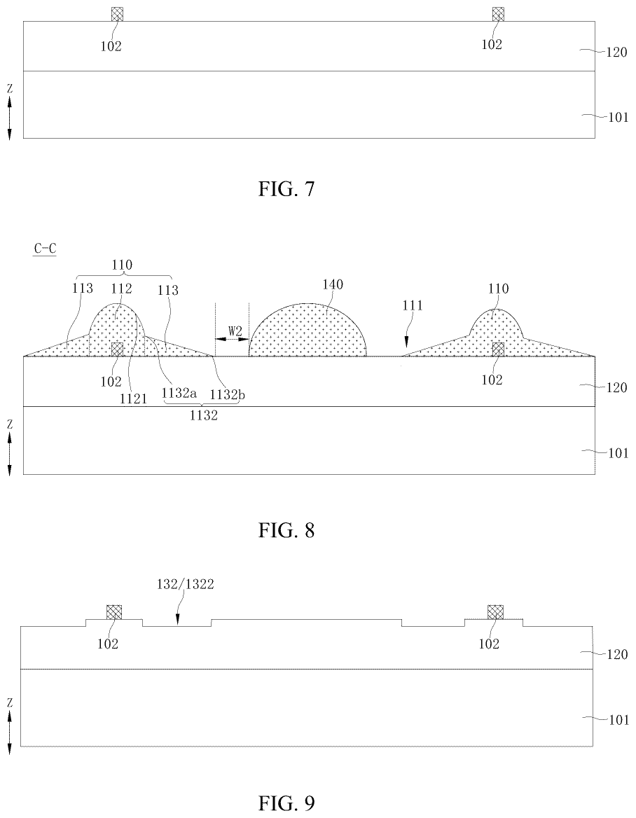

It should be noted that, referring to FIG. 7 and FIG. 8, the display panel 100 may not be provided with the first embedding portion 131 and the second embedding portion 132, thereby simplifying the preparation process of the second insulating layer 120.

In some embodiments, a surface of the second insulating layer 120 facing away from the substrate 101 is a rough surface. That is, a surface of the second insulating layer 120 in contact with the first insulating layer 110 is a rough surface, and the rough surface helps to increase the contact area between the first insulating layer 110 and the second insulating layer 120, so that the insulating layer 102 and the substrate 101 are not easy to peeled off, thereby ensuring the touch performance of the touch trace 102 and reducing the risk of failure of the touch trace 102. The principle thereof has been described and will not be repeated.

In some embodiment of the present disclosure, a roughness of the rough surface ranges from 5 nm to 10 nm, thereby preventing the roughness of the rough surface from being too small, and increasing the contact area between the first insulating layer 110 and the second insulating layer 120. In addition, the roughness of the rough surface can also be prevented from being too large, thereby reducing the adverse effect of the rough surface on the preparation of the touch trace 102. For example, the roughness of the rough surface may be 5 nm, 6 nm, 7 nm, 8 nm, 9 nm, 10 nm or any value ranging from 5 nm to 10 nm.

In some embodiments, referring to FIG. 2 and FIG. 6, the sidewall of the first opening 111 includes first sidewalls 1111 that are connected end to end in sequence, and extending directions of two adjacent first sidewalls 1111 are different. That is, an outer contour of an orthographic projection of the first opening 111 on the substrate 101 includes multiple first side edges that are arranged along a circumferential direction of the first opening 111. Two adjacent first side edges are connected, and extending directions of the two adjacent first side edges are different. A side of at least one first sidewall 1111 facing the first opening 111 is correspondingly provided with an auxiliary portion 113. In the same first opening 111, a side of some partial amount of the first sidewalls 1111 facing the first opening 111 is correspondingly provided with the auxiliary portion 113. A side of other partial amount of the first sidewalls 1111 facing the first opening 111 is not provided with the auxiliary portion 113. In an embodiment of the present disclosure, in the same first opening 111, a side of each of the first sidewalls 1111 facing the first opening 111 is correspondingly provided with the auxiliary portion 113.

In some embodiments, referring to FIG. 2, in the corresponding first sidewall 1111 and auxiliary portion 113, a width of the auxiliary portion 113 along an extension direction perpendicular to the first sidewall 1111 is a first width W1. The first width W1 gradually increases from a center to an edge of the extension direction of the first sidewall 1111, increasing an area of the auxiliary portion 113, and increasing the contact area between the first insulating layer 110 and the second insulating layer 120. As a result, the touch trace 102 is not easily peeled off from the substrate 101, thereby ensuring the touch performance of the touch trace 102 and reducing the risk of failure of the touch trace 102. The principle thereof has been described and will not be repeated.

In some embodiments, referring to FIG. 6, in the corresponding first sidewall 1111 and auxiliary portion 113, a width of the auxiliary portion 113 along the extension direction perpendicular to the first sidewall 1111 is the first width W1. The first width W1 is the same along the extension direction of the first sidewall 1111, thereby making the shape of the first sidewall 1111 relatively simple, and reducing the production difficulty of the first opening 11.

In some embodiments, referring to FIG. 3 and FIG. 10, a surface of a side of the body portion 112 facing away from the substrate 101 is the first surface 1121 that is an arc-shaped surface, and the first surface 1121 protrudes in a direction facing away from the substrate 101, so that an area of the first surface 1121 is larger, improving a contact area between the first surface 1121 and a film layer subsequently formed at the first surface 1121, thereby improving the connection stability between the first surface 1121 and the film layer subsequently formed at the first surface 1121.

In some embodiments, referring to FIG. 3, the auxiliary portion 113 includes a second surface 1132. The first surface 1121 of the body portion 112 is connected to the second surface 1132 of the auxiliary portion 113. The second surface 1132 is an arc-shaped surface, and the second surface 1132 is arranged to protrude facing away from the body portion 112. As a result, an area of the second surface 1132 is larger, improving a contact area between the second surface 1132 and a film layer subsequently formed at the second surface 1132, thereby improving the connection stability between the second surface 1132 and the film layer subsequently formed at the second surface 1132.

In some other embodiments, referring to FIG. 8 and FIG. 10, the auxiliary portion 113 includes a second surface 1132. The first surface 1121 of the body portion 112 is connected to the second surface 1132 of the auxiliary portion 113. The second surface 1132 is an inclined surface. The second surface 1132 includes a first end 1132a and a second end 1132b opposite to each other. The first end 1132a is adjacent to the body portion 112, and the second end 1132b is facing away from the body portion 112. The first end 1132a is tilted relative to the second end 1132b in a direction facing away from the substrate 101. In this way, the shape of the second surface 1132 is relatively simple, thereby reducing the production difficulty of the second surface 1132.

In some embodiment of the present disclosure, referring to FIG. 3, a maximum value of a distance between the second surface 1132 of the auxiliary portion 113 and the substrate 101 is less than a maximum value of a distance between the first surface 1121 of the body portion 112 and the substrate 101. For example, a maximum thickness of the auxiliary portion 113 is less than a maximum thickness of the body portion 112. In this way, when light is emitted from the light extraction member 140, the second surface 1132 of the auxiliary portion 113 adjacent to the light extraction member 140 blocks less of the emitted light, thereby reducing the amount of light entering the adjacent auxiliary portion 113, and increasing the light output of the display panel 100.

In some embodiments, referring to FIG. 1 and FIG. 3, the display panel 100 further includes light extraction members 140 that are arranged at a side of the substrate 101 facing the first insulating layer 110. The light extraction members 140 can be arranged in one-to-one correspondence with the first openings 111, and the light extraction member 140 are located in the corresponding first opening 111. The light extraction members 140 can reduce light loss and increase the light extraction amount, thereby improving the display effect.

In some embodiments, referring to FIG. 13, a side surface of the light extraction member 140 is a third surface 143. The third surface 143 is an arc-shaped surface, and the third surface 143 is arranged to protrude in a direction facing away from the center of the light extraction member 140. In this way, an area of the third surface 143 is larger, improving a contact area between the third surface 143 and a film layer subsequently formed at the third surface 143, thereby improving the connection stability between the third surface 143 and the film layer subsequently formed at the third surface 143. In addition, it is further beneficial to improve the brightness of the display panel 100 at a large viewing angle and improve a color difference of the display panel 100.

In some embodiment of the present disclosure, an angle between the side surface of the light extraction member 140 and the substrate 101 ranges from 70° to 85°, that is, an angle between the third surface 143 and the substrate 101 ranges from 70° to 85°, thereby preventing the angle between the side surface of the light extraction member 140 and the substrate 101 from being too small, improving the brightness of the display panel 100 at a large viewing angle and improving the color difference of the display panel 100. In addition, the angle between the side surface of the light extraction member 140 and the substrate 101 can be prevented from being too large, thereby improving the area of the third surface 143. For example, the angle between the side surface of the light extraction member 140 and the substrate 101 may be 70°, 75°, 80°, 85°, or any value ranging from 70° to 85°.

In an embodiment in which the third surface 143 is an arc-shaped surface, the angle between the side surface of the light extraction member 140 and the substrate 101 may be: an angle between a virtual plane tangent to the side surface of the light extraction member 140 and the substrate 101.

In some embodiment of the present disclosure, referring to FIG. 13, a surface of a side of the light extraction member 140 facing away from the substrate 101 is a flat surface, and the fourth surface 144 of the light extraction member 140 is a flat surface, so that a structure of the surface of the side of the light extraction member 140 facing away from the substrate 101 is relatively simple, thereby reducing the production difficulty of the surface of the side of the light extraction member 140 facing away from the substrate 101.

In some other examples, the fourth surface 144 may be an arc-shaped surface, and a shape of the fourth surface 144 is not limited in the embodiments of the present disclosure.

In some embodiment of the present disclosure, referring to FIG. 2, in the same first opening 111, a minimum value (i.e., the minimum distance) of a distance W2 between the light extraction member 140 and the auxiliary portion 113 is greater than or equal to 1 μm, that is, the minimum value of the distance W2 between the light extraction member 140 and the adjacent first insulating layer 110 is greater than or equal to 1 μm. In this way, when light is emitted from the light extraction member 140, the auxiliary portion 113 adjacent to the light extraction member 140 blocks less of the emitted light, thereby reducing the amount of light entering the adjacent auxiliary portion 113, and increasing the light output of the display panel 100. In addition, it is beneficial to reduce the difficulty of configuring the distance between the light extraction member 140 and the auxiliary portion 113. For example, in the same first opening 111, the minimum value of the distance W2 between the light extraction member 140 and the auxiliary portion 113 may be 1 μm, 1.5 μm, 2 μm, 2.5 μm, or any value greater than 1 μm.

In some embodiment of the present disclosure, the light extraction member 140 and the first insulating layer 110 are arranged in a same layer, thereby simplifying the preparation process of the light extraction member 140 and the first insulating layer 110, and reducing the preparation cost. For example, the material of the first insulating layer 110 and the light extraction member 140 may include a material with a high refractive index.

It should be noted that, “arranged in a same layer” in the embodiments of the present disclosure means that multiple film layers are formed of a same material using a same or different process, but are not necessarily located at a same horizontal plane or have a same thickness.

In some embodiment of the present disclosure, referring to FIG. 2, in the same first opening 111, the distance W2 between the light extraction member 140 and the first insulating layer 110 is the same along the circumferential direction of the light extraction member 140, so that a shape of the orthographic projection of the light extraction member 140 on the substrate 101 is matched with a shape of the orthographic projection of the first opening 111 on the substrate 101, thereby improving the coverage area of the light extraction member 140 and the first insulating layer 110.

In some embodiments, referring to FIG. 2, a size W3 of the body portion 112 along the extending direction perpendicular to the body portion 112 ranges from 3 μm to 5 μm, thereby preventing the size W3 of the body portion 112 along the extending direction perpendicular to the body portion 112 from being too small, which is beneficial for the body portion 112 to better cover the touch trace 102. In addition, the size W3 of the body portion 112 along the extending direction perpendicular to the body portion 112 can also be prevented from being too large, thereby providing more configuration space for the auxiliary portion 113. For example, the size W3 of the body portion 112 along the extending direction perpendicular to the body portion 112 may be 3 μm, 3.5 μm, 4 μm, 4.5 μm, 5 μm, or any value ranging from 3 μm to 5 μm.

In some embodiment of the present disclosure, referring to FIG. 2, the size W1 of the auxiliary portion 113 along the extending direction perpendicular to the body portion 112 is less than or equal to 3.5 μm, so that the size W1 of the auxiliary portion 113 along the extending direction perpendicular to the body portion 112 can also be prevented from being too large, thereby preventing the auxiliary portion 113 from affecting the layout of the light extraction member 140. For example, the size W1 of the auxiliary portion 113 along the extending direction perpendicular to the body portion 112 may be 1 μm, 2 μm, 3 μm, 3.5 μm, or any value less than 3.5 μm.

The touch trace 102 and the auxiliary touch trace provided by the embodiments of the present disclosure are further described below.

In some embodiments, the touch trace 102 may surround to form second openings, and the second opening is correspondingly arranged with the first opening 111. An orthographic projection of the first opening 111 on the substrate 101 are located within an orthographic projections of the corresponding second opening on the substrate 101. In this case, the touch trace 102 may intersect and form a grid structure.

In some embodiments, the touch trace 102 may include multiple first touch electrodes extending along the first direction X and multiple second touch electrodes extending along the second direction Y. The first touch electrode and the second touch electrode are staggered (i.e., intersecting) with each other. Each of the first touch electrodes may include first touch electrode blocks that are arranged along the first direction X. The first touch electrode blocks may be formed as a grid structure by the touch traces 102 intersecting each other. Each of the second touch electrodes may include second touch electrode blocks that are arranged along the second direction Y. The second touch electrode blocks may be formed as a grid structure by the touch traces 102 intersecting each other. Since the touch electrode blocks (the first touch electrode block and the second touch electrode block) are formed as the grid structure, the touch electrode blocks of the grid structure may be located in a non-opening area of the display panel 100, so that the grid structure does not block the opening area, thereby reducing the influence of the touch traces 102 on the light emission of the light emitting device layer, and reducing the influence of the touch traces 102 on the display effect of the display area.

In some embodiment of the present disclosure, the touch electrode blocks of one of the first touch electrode and the second touch electrode may be connected by a touch trace 102 to form an uninterrupted structure. The touch electrode blocks of another one of the first touch electrode and the second touch electrode are disconnected and can be connected through a bridge formed by the auxiliary touch traces. The bridge can be located at an intersection position of the first touch electrode and the second touch electrode, so that the first touch electrode and the second touch electrode are prevented from being short-circuited at the intersection position.

In some embodiment of the present disclosure, one of the first touch electrode and the second touch electrode is a driving electrode, and another one of the first touch electrode and the second touch electrode is a sensing electrode (a detection electrode).

In some embodiment of the present disclosure, a material of at least one of the auxiliary touch trace and the touch trace 102 may include metals such as titanium, silver, copper, aluminum, and molybdenum, or alloys, or any one or more of a conductive oxide (such as indium tin oxide (ITO), indium zinc oxide (IZO), zinc oxide (ZnO), aluminum zinc oxide (AZO)), gallium zinc oxide, tantalum titanium oxide, tin oxide, cadmium oxide, and indium oxide.

The light-emitting device layer provided by the embodiments of the present disclosure will be described below.

In some embodiments, the light-emitting device layer includes light-emitting units that are spaced apart along the thickness direction perpendicular to the substrate 101. For example, the light-emitting units may be arranged in an array. The first openings 111 may be arranged in one-to-one correspondence with the light-emitting units. An orthographic projection of the light-emitting unit on the substrate 101 overlaps an orthographic projection of the corresponding first opening 111 on the substrate 101. For example, the orthographic projection of the light-emitting unit on the substrate 101 may be located within the orthographic projection of the corresponding first opening 111 on the substrate 101. The orthographic projection of the light-emitting unit on the substrate 101 overlaps the orthographic projection of the corresponding light extraction member 140 on the substrate 101. For example, the orthographic projection of the light-emitting unit on the substrate 101 is located within the orthographic projection of the corresponding light extraction member 140 on the substrate 101.

In an embodiment of the present disclosure, that A is correspondingly arranged with B may refer to: one A is correspondingly arranged with at least one B, or one B is correspondingly arranged with at least one A. In the embodiments of the present disclosure, one A being correspondingly arranged with one B is taken as an example for explanation. For example, the light-emitting unit being correspondingly arranged with the first opening 111 may mean that one light-emitting unit is correspondingly arranged with at least one first opening 111, or one first opening 111 is correspondingly arranged with at least one light-emitting unit.

In some embodiments, the light-emitting unit may include a first electrode, a light-emitting material, and a second electrode stacked in sequence along a direction facing away from the substrate 101, and the first electrode may be arranged at a side of the light-emitting material facing the substrate 101. One of the first electrode and the second electrode may be an anode, and the other of the first electrode and the second electrodes may be a cathode.

In some embodiment of the present disclosure, the light-emitting unit may further include one or more of a hole injection layer (HIL), a hole transport layer (HTL), an electron injection layer (EIL), an electron transport layer (ETL), a hole block layer (HBL), and an electron block layer (EBL).

In some embodiment of the present disclosure, the light-emitting units include, but are not limited to, a red light-emitting unit, a green light-emitting unit, and a blue light-emitting unit. In other examples, the light-emitting units may further include a white light-emitting unit.

The various technical features of the above embodiments can be combined in any way. In order to make the description concise, not all possible combinations of the technical features in the foregoing embodiments are described. However, as long as there is no contradiction between the combinations of the technical features, it should be considered as a scope of the specification.

The above embodiments merely express several embodiments of the present disclosure, and the description thereof is more specific and detailed, but should not be construed as limiting the scope of the claims. It can be understood that those skilled in the art may make several modifications and improvements without departing from the concept of the present disclosure, which fall within the scope of the present disclosure. Therefore, the scope of the present disclosure shall be defined by the appended claims.

What is claimed is:

1. A display panel, comprising:
a substrate;
a touch trace provided at a side of the substrate; and
a first insulating layer provided at a side of the touch trace facing away from the substrate;
wherein the first insulating layer comprises a body portion and an auxiliary portion that are connected to each other, the body portion surrounds to form first openings spaced from one another, and the auxiliary portion is arranged at a side of the body portion facing one of the first openings; and
in a thickness direction of the substrate, the body portion covers the touch trace, and the auxiliary portion does not overlap the touch trace.

2. The display panel according to claim 1, further comprising: a second insulating layer located between the touch trace and the substrate;
wherein a first embedding portion is provided at a side of the first insulating layer facing the substrate, a second embedding portion is provided at a side of the second insulating layer facing away from the substrate, and the first embedding portion and the second embedding portion are embedded with each other.

3. The display panel according to claim 2, wherein the first embedding portion comprises a first embedding sub-portion, the second embedding portion comprises a second embedding sub-portion, and the first embedding sub-portion and the second embedding sub-portion are embedded with each other; and
the first embedding sub-portion is arranged on the auxiliary portion.

4. The display panel according to claim 2, wherein the first embedding portion comprises a third embedding sub-portion, the second embedding portion comprises a fourth embedding sub-portion, and the third embedding sub-portion and the fourth embedding sub- portion are embedded with each other; and
the third embedding sub-portion is arranged on the body portion.

5. The display panel according to claim 3, wherein on the same auxiliary portion, first embedding sub-portions are provided and spaced from one another.

6. The display panel according to claim 2, wherein a surface of the second insulating layer facing away from the substrate is a rough surface, and a roughness of the rough surface ranges from 5 nm to 10 nm.

7. The display panel according to claim 2, wherein one of the first embedding portion and the second embedding portion is a groove, the other one of the first embedding portion and the second embedding portion is a protrusion, and the groove and the protrusion are embedded with each other;
an aperture size of the groove is smaller than a size of a bottom wall of the groove;
and/or
an opening size of the groove gradually decreases from the bottom wall toward an aperture of the groove;
and/or
a depth of the groove ranges from 0.3 μm to 0.5 μm.

8. The display panel according to claim 1, wherein a sidewall of each of the first openings comprises first sidewalls connected end to end in sequence, extending directions of two adjacent first sidewalls are different, and at least one of the first sidewalls is provided with the auxiliary portion at a side facing the first openings.

9. The display panel according to claim 8, wherein in the corresponding first sidewall and the auxiliary portion, a width of the auxiliary portion along a direction perpendicular to an extending direction of the first sidewall is a first width, and the first width gradually increases from a center to an edge of the extending direction of the first sidewall.

10. The display panel according to claim 8, wherein in the corresponding first sidewall and the auxiliary portion, a width of the auxiliary portion along a direction perpendicular to an extension direction of the first sidewall is a first width, and the first width is constant along the extension direction of the first sidewall.

11. The display panel according to claim 1, wherein a surface of the body portion facing away from the substrate is a first surface, the first surface is formed as an arc-shaped surface and protrudes in a direction facing away from the substrate; and/or
the auxiliary portion comprises a second surface, and a surface of the body portion facing away from the substrate is connected to the second surface; the second surface is formed as an arc-shaped surface and protrudes in a direction facing away from the body portion; or the second surface is formed as an inclined surface and comprises a first end adjacent to the body portion and a second end facing away from the body portion, and the first end is inclined in a direction facing away from the substrate relative to the second end; and/or
a maximum thickness of the auxiliary portion is less than a maximum thickness of the body portion.

12. The display panel according to claim 1, further comprising: light extraction members provided at a side of the substrate facing the first insulating layer, and the light extraction members are correspondingly arranged in the first openings.

13. The display panel according to claim 12, wherein a side surface of each of the light extraction members is a third surface, and the third surface is formed as an arc-shaped surface and protrudes facing away from a center of the light extraction member; and/or
an angle between the side surface of the light extraction member and the substrate ranges from 70° to 85°; and/or
a surface of the light extraction member facing away from the substrate is a flat surface; and/or
in a same first opening, a minimum distance between the light extraction member and the auxiliary portion is greater than or equal to 1 μm; and/or
the light extraction member and the first insulating layer are arranged in a same layer; and/or
in a same first opening, a distance between the light extraction member and the first insulating layer is constant along a circumferential direction of the light extraction member.

14. The display panel according to claim 1, wherein a size of the body portion along a direction perpendicular to an extending direction of the body portion ranges from 3 μm to 5 μm; and/or
a size of the auxiliary portion along a direction perpendicular to an extension direction of the body portion is less than or equal to 3.5 μm.

15. The display panel according to claim 1, wherein the body portion defines first openings that are spaced from one another.

16. A display apparatus, comprising a display panel,
wherein the display panel comprises:
a substrate;
a touch trace provided at a side of the substrate; and
a first insulating layer provided at a side of the touch trace facing away from the substrate;
wherein the first insulating layer comprises a body portion and an auxiliary portion that are connected to each other, the body portion surrounds to form first openings spaced from one another, and the auxiliary portion is arranged at a side of the body portion facing one of the first openings; and
in a thickness direction of the substrate, the body portion covers the touch trace, and the auxiliary portion does not overlap the touch trace.
